(19) United States
(12) Patent Application Publication
(10) Pub. No.: US 2012/0222887 A1
(43) Pub. Date: Sep. 6, 2012

(54) PARTIALLY MULTILAYERED WIRING BOARD AND METHOD OF MANUFACTURING PARTIALLY MULTILAYERED WIRING BOARD

(75) Inventors: Shinichi NIKAIDO, Sakura-shi (JP); Toshiyuki HAYAMI, Sakura-shi (JP)

(73) Assignee: FUJIKURA LTD., Tokyo (JP)

(21) Appl. No.: 13/474,423

(22) Filed: May 17, 2012

Related U.S. Application Data
(63) Continuation of application No. PCT/JP2010/062612, filed on Jul. 27, 2010.

(30) Foreign Application Priority Data
Nov. 18, 2009 (JP) 2009-262599

(51) Int. Cl. H05K 1/02; B32B 38/10

(52) U.S. Cl. 174/250; 156/182

(57) ABSTRACT

In order to provide a partially multilayered wiring board without exposing circuits of a mother board printed board even if not separately performing protection process, such as gold plating, a partially multilayered wiring board 1 has a first insulating base material 11 having one main surface formed thereon with first conductive circuit patterns 21 and a second insulating base material 12 laminated on the one main surface of the first insulating base material 11 and having one main surface formed thereon with second conductive circuit patterns 22 smaller than a region where the first conductive circuit patterns 21 are formed, wherein the first conductive circuit patterns 21 are covered by other main surface of the second insulating base material 22.

### BACKGROUND OF THE INVENTION

1. Technical Field of the Invention

The present invention relates to a partially multilayered wiring board, which is used for mobile phones etc. and in which the number of laminating is partially different, and to a method of manufacturing the same.

The present application claims priority from Japanese Patent Application No. 2009-262599, filed on Nov. 18, 2009, and International Application PCT/JP2010/62612, filed on Jul. 27, 2010, which are incorporated by reference in their entity and which are to be a part of the description and/or drawings of the present application.

2. Description of the Related Art

For manufacturing a multilayered wiring board, a method is known which is directed to a partially multilayered wiring board wherein the number of laminating is partially different, particularly to a rigid flex printed wiring board including a rigid portion and a flex portion, and the method comprises: outer shape processing a wiring-circuit-added board to be smaller than a mother board printed wiring board; attaching the wiring-circuit-added board to the mother board printed board; and, prior to or subsequent to the attaching step, forming a cover layer having an opening at a region where the wiring-circuit-added board is attached (Japanese unexamined Patent Publication No. 2008-288612 (Patent Document 1)).

### PRIOR ART DOCUMENT(S)

[Patent Document(s)]

[Patent Document 1] Japanese unexamined Patent Publication No. 2008-288612

### SUMMARY OF THE INVENTION

### Problems to be Solved by the Invention

However, if such a cover layer is formed to have an opening at a region where the wiring-circuit-added board is attached as the prior art technique, then a gap is created between the opening of the cover layer and the wiring-circuit-added board, and the circuit of the mother board printed wring board is exposed, so that problems occur including that the exposed circuit requires separately a protection treatment, such as gold plating, thereby increasing steps for manufacturing.

Problems to be solved by the present invention include providing a partially multilayered wiring board in which one or more wiring-circuit-added boards are partially laminated while allowing the circuit of the wiring board to be protected without separately performing a protection treatment, such as gold plating.

### Means for Solving the Problems

The present invention solves the above problems by providing a partially multilayered wiring board comprising: a first insulating base material having one main surface formed thereon with a first conductive circuit pattern; and a second insulating base material laminated on a side of the one main surface of the first insulating base material and having one main surface formed thereon with a second conductive circuit pattern smaller than a region where the first conductive circuit pattern is formed, wherein the first conductive circuit pattern is covered by other main surface of the second insulating base material.

In the above invention, a region not formed thereon with the first conductive circuit pattern within the one main surface of the first insulating base material and/or a region not formed thereon with the second conductive circuit pattern within the one main surface of the second insulating base material may be roughened.

In the above invention, a configuration may be adopted wherein the partially multilayered wiring board further comprises a third insulating base material laminated on a side of the one main surface of the second insulating base material and having one main surface formed thereon with a third conductive circuit pattern, and the third insulating base material is laminated on the second insulating base material such that the one main surface of the second insulating base material is contacted with other main surface of the third insulating base material.

In the above invention, a configuration may be adopted wherein the partially multilayered wiring board has: a fourth conductive pattern formed on other main surface of the first insulating base material; a fifth insulating base material laminated on a side of the other main surface of the first insulating base material and having other main surface, of one and other main surfaces, formed thereon with a fifth conductive circuit pattern smaller than a region where the fourth conductive circuit pattern is formed; and a sixth insulating base material laminated on a side of the other main surface of the fifth insulating base material and having other main surface, of one and other main surfaces, formed thereon with a sixth conductive circuit pattern, and wherein the fourth conductive circuit pattern is covered by the one main surface of the fifth insulating base material, and the fifth conductive circuit pattern is covered by the one main surface of the sixth insulating base material.

The present invention according to another aspect solves the above problems by a method comprising: preparing a first sheet in which a first conductive layer is laminated on one main surface of a first insulating base material and a second sheet in which a second conductive layer is laminated on one main surface of a second insulating base material; removing a predetermined portion of the first conductive layer of the first sheet to form a first conductive circuit pattern on the one main surface of the first insulating base material; attaching the second sheet such that the first conductive circuit pattern is covered by other main surface of the second insulating base material; and removing a predetermined portion of the second conductive layer of the attached second sheet to form a second conductive circuit pattern on the one main surface of the second insulating base material.

In the above invention, the method may further comprise a step of preparing a third sheet in which a third conductive layer is laminated on one main surface of a third insulating base material, wherein the third sheet may be attached such that the second conductive circuit pattern is contacted with other main surface of the third insulating base material after the second conductive circuit pattern has been formed, and a predetermined portion of the third conductive layer of the attached third sheet may be removed to form a third conductive circuit pattern on the one main surface of the third insulating base material.

In the above invention, a protecting layer may be formed as an uppermost layer to cover a conductive circuit pattern of an insulating base material.

### Advantageous Effect of the Invention

According to the present invention, since the first conductive circuit pattern is covered by the other main surface of the second insulating base material, entirety of the first conductive circuit pattern is protected by the second insulating base material formed thereon with the second conductive pattern. As a result, it comes to be unnecessary to separately perform protection treatment, such as gold plating, and the production steps are thus allowed to be simplified. In addition, the partially multilayered wiring board according to the present invention does not require a cover layer to be separately provided for covering the conductive circuit pattern other than a portion where the multilayered portion is provided, and the thickness of the partially multilayered wiring board is thus allowed to be reduced. Consequently, according to the method of manufacturing the partially multilayered wiring board of the present invention, partially multilayered wiring boards can be provided which allow the material cost to be reduced and which are more flexible compared to the conventional method.

### BRIEF DESCRIPTION OF DRAWINGS

FIG. 1A is a plan view of a partially multilayered wiring board according to embodiments of the present invention;

FIG. 1B is a cross-sectional view along line IB-IB shown in FIG. 1A;

FIG. 2A depicts first process views for explaining a method of manufacturing the partially multilayered wiring board shown in FIG. 1A and FIG. 1B;

FIG. 2B depicts second process views for explaining the method of manufacturing the partially multilayered wiring board shown in FIG. 1A and FIG. 1B;

FIG. 3A depicts first process views for explaining a method of manufacturing a partially multilayered wiring board according to another embodiment of the present invention; and

FIG. 3B depicts second process views for explaining the method of manufacturing the partially multilayered wiring board according to another embodiment of the present invention.

### DESCRIPTION OF THE PREFERRED EMBODIMENT

### First Embodiment

Hereinafter, a partially multilayered wiring board 1 of the first embodiment according to the present invention will be described with reference to the drawings.

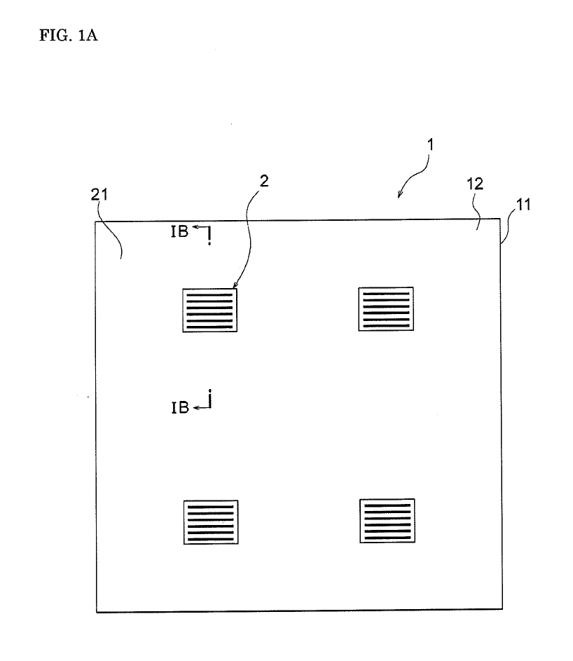

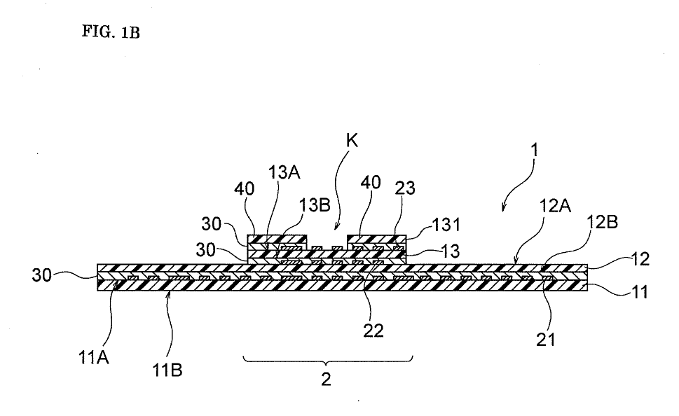

FIG. 1A is a plan view of the partially multilayered wiring board according to the present embodiment, and FIG. 1B is a cross-sectional view along line IB-IB shown in FIG. 1A. As shown in FIG. 1A and FIG. 1B, the partially multilayered wiring board 1 according to the present embodiment has multilayered portions 2 in which each number of laminating is different from those of other portions.

As shown in FIG. 1B, one main surface 11A of a first insulating base material 11 is formed thereon with first conductive circuit patterns 21. In addition, one main surface 12A of a second insulating base material 12, which is laminated on the one main surface side of the first insulating base material 11, is formed thereon with second conductive circuit patterns 22. Furthermore, each third insulating base material 13, which is laminated on the one main surface 12A side of the second insulating base material 12, is formed thereon with third conductive circuit patterns 23. As shown in the same figure, the partially multilayered wiring board according to embodiments has a partially multilayered structure in which the area of regions where the second conductive circuit patterns 22 and the third conductive circuit patterns 23 are formed is smaller than the area of a region where the first conductive circuit patterns 21 are formed.

Thus, the partially multilayered wiring board 1 according to the present embodiment is configured such that the first insulating base material 11, the first conductive circuit patterns 21, the second insulating base material 12, the second conductive circuit patterns 22, the third insulating base materials 13, the third conductive circuit patterns 23, and protecting layers 40 are laminated directly or indirectly via adhesives 30 in this order from the lowermost layer. Each opening K where the third conductive circuit patterns 23 are exposed is to be a section where one or more electronic components are mounted. Note that, alternatively or in addition to the above, one or more multilayered portions 2 are possible to be formed on the other main surface 11B side of the first insulating base material 11.

Specifically in the present embodiment, the first conductive circuit patterns 21 formed on the one main surface 11A of the first insulating base material 11 are covered by the other main surface 12B of the second insulating base material 12. That is, the other main surface 12B of the second insulating base material 12 contacts with the one main surface 11A of the first insulating base material 11 such that the first conductive circuit patterns 21 are interposed therebetween. Note that the other main surface 12B of the second insulating base material 12 and the one main surface 11A of the first insulating base material 11 adhere to each other by adhesive.

In addition, each third insulating base material 13 is laminated on the second insulating base material 12 such that the other main surface 13B of the third insulating base material 13 contacts with the one main surface 12A of the second insulating base material 12.

As shown in the same figure, the partially multilayered wiring board 1 according to the present embodiment is configured such that the other main surfaces (the rear surfaces) of insulating base materials 10 laminated at the upper layer side cover conductive circuit patterns 20 as respective lower layers, thereby eliminating the necessity of a cover layer to be provided on the conductive circuit patterns 20 other than portions on which multilayered portions 2 are provided.

In case of providing a cover layer on a region other than the multilayered portions, a sufficient clearance is required to be provided between an area where each multilayered portion is to be formed and an opening of the cover layer with such an extent that the multilayered portion is allowed to be subsequently laminated, however, if do so, a gap will be created between the laminated multilayered portion and the cover layer, thereby requiring separately a protection treatment, such as gold plating. In contrast, according to the present embodiment, since the first conductive circuit patterns 21 are covered by the other main surface of the second insulating base material, a gap is inherently not to be created thereby not requiring separately a protection treatment, such as gold plating. As a result, the production steps are allowed to be simplified, as will be described later.

In addition, the partially multilayered wiring board 1 according to the present embodiment does not require to be separately provided with a cover layer for covering the conductive circuit patterns 20 other than portions where the multilayered portions 2 are provided, and the thickness of the partially multilayered wiring board 1 is thus allowed to be reduced. In this manner, according to the method of manufacturing the partially multilayered wiring board of the present embodiment, material cost may be reduced compared to the conventional method, and it is possible to provide a partially multilayered wiring board with more flexibility.

That is, in each multilayered portion 2 as shown in FIG. 1B, respective one layer of insulating base materials 10 (12, 13) and one layer of adhesive layer for causing these insulating base materials 10 to adhere with each other are only placed between the conductive circuit patterns 20 (21, 22, 23), and therefore, the entire thickness of the partially multilayered wiring board 1 is allowed to be reduced.

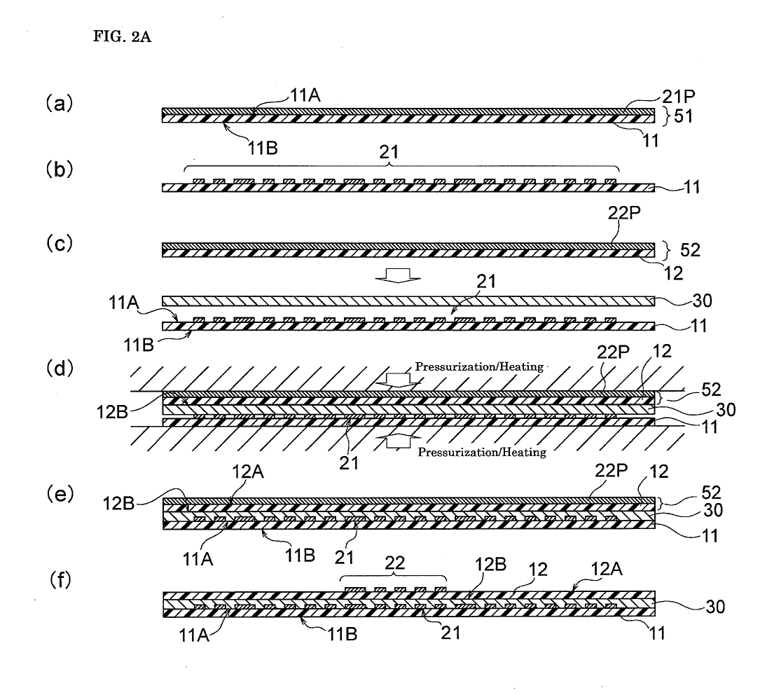

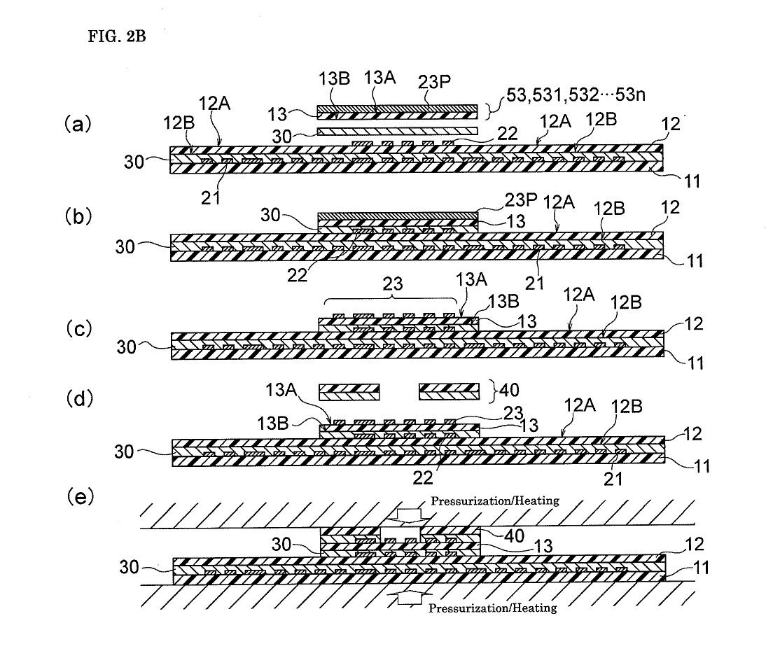

With reference to FIG. 2A and FIG. 2B, a method of manufacturing the partially multilayered wiring board 1 according to the present embodiment will then be described. FIG. 2A illustrates steps of forming the second conductive circuit patterns 22, and FIG. 2B illustrates steps of forming the third conductive circuit patterns 23 and the protecting layers 40 covering them.

First of all, a first sheet 51 is prepared in which a first conductive layer 21P is attached to one main surface 11A of first insulating base material 11, as shown in (a) of FIG. 2A. The first sheet 51 is a sheet in which a metal foil, such as copper, is formed on one main surface of a resin sheet (first insulating base material 11), such as polyimide (PI), having flexibility and being of thickness of 10 μm to 75 μm. Polyethylene terephthalate (PET), polyethylene naphthalate (PEN) etc. may also be used as the first insulating base material 11.

Subsequently, an etching process is performed using copper (II) chloride or alkali etchant liquid etc. to remove a predetermined portion of the first conductive layer 21P thereby forming first conductive circuit patterns 21 on one main surface 11A of the first insulating base material 11, as shown in (b) of the same figure. After removing the predetermined portion of the first conductive layer 21P through the etching process, a roughened surface of the first insulating base material 11 appears at a region not formed thereon with the first conductive circuit patterns 21 within the one main surface 11A of the first insulating base material 11. According to the present embodiment, the surface roughness degree of at least the region not formed thereon with the first conductive circuit patterns 21 within the one main surface 11A of the first insulating base material 11 is larger than the surface roughness degree of the other main surface 11B of the first insulating base material 11.

This is due to the following reasons. The first sheet 51 according to the present embodiment, which has a configuration where the first insulating base material 11 and the first conductive layer 21P are attached to each other, is produced such that the adhesion surface of the first conductive layer 21P is roughened in order to enhance the adhesive strength between the first insulating base material 11 and the first conductive layer 21P. When the one main surface 11A of the first insulating base material 11 is attached to that roughened adhesion surface, the irregular figure formed on the adhesion surface of the first conductive layer 21P is transferred to the one main surface 11A of the first insulating base material 11, thereby forming a corresponding irregularity on the one main surface 11A of the first insulating base material 11. Thereafter, if the first conductive layer 21P is removed by etching process, then there appears the roughened one main surface 11A of the first insulating base material 11. Consequently, the roughened surface appears within the region where the first conductive layer 21P has been removed, that is, where the first conductive circuit patterns 21 is not formed. The irregularity of the roughened surface increases the surface area thereby contributing to enhancement of the adhesion properties between the one main surface of the first insulating base material 11 and the other main surface 12B of the second insulating base material 12 to be laminated thereon.

It should be appreciate that the surface of the roughened region has irregularity and a condition is obtained where the surface roughness degree, such as the center line average roughness (Ra), the maximum height (Rmax), the ten-point average height (Rz), or the like, falls within a predetermined range of value.

Prior to or subsequent to the above steps shown in (a), (b) of the same figure, a second sheet 52 is prepared in which a second conductive layer 22P is laminated on one main surface 12A of second insulating base material 12. According to the present embodiment, a sheet of the same quality as the first sheet 51 is used as the second sheet 52 in order to suppress the influence caused by shrinkage due to heat. By laminating base materials of substantially the same heat expansion coefficients, warpage is hard to occur when shrinkage is generated due to heat and the like, and the force acting on attached portions is allowed to be reduced thereby ensuring the reliability.

Subsequently, the prepared second sheet 52 is attached via epoxy-base adhesive 30 to the one main surface 11A of the first insulating base material 11 which has been formed thereon with the first conductive circuit patterns 21 made in the step shown in (b) of the same figure. Gaps in the irregularity for circuitry resulting from the first conductive circuit patterns 21 are filled with the adhesive 30.

Further, as shown in (d) of the same figure, the second sheet 52 is attached to the one main surface 11A side of the first insulating base material 11 by using pressing molds to press them from both main surface sides under a predetermined heating/pressurization environment.

(e) of the same figure illustrates the second sheet 52 and the first insulating base material 11 integrated with each other after being removed from the pressing molds.

Thereafter, an etching process is performed using copper (II) chloride or alkali etchant liquid etc. to remove a predetermined portion of the second conductive layer 22P thereby forming second conductive circuit patterns 22 on one main surface 12A of the second insulating base material 12, as shown in (f) of the same figure. As previously described, since the predetermined portion of the second conductive layer 22P is removed by the etching process, the one main surface 12A of the second insulating base material 12 not formed thereon with the second conductive circuit patterns 22 is roughened. Therefore, the adhesion properties are allowed to be enhanced between the one main surface 12A of the second insulating base material 12 and other main surfaces 13B (opposing one main surfaces 13A) of third insulating base materials 13, which will be described later.

With reference to FIG. 2B, the steps will then be described for forming the third conductive circuit patterns 23 and the protecting layers 40 covering them.

First, each third sheet 53 is prepared in which a third conductive layer 23P is laminated on one main surface 13A of third insulating base material 13, as shown in (a) of FIG. 2B. The third sheet 53 is formed as being smaller than the first sheet 51. According to the present embodiment, a sheet of the same quality as the first sheet 51 is used as the third sheet 53 in order to suppress the influence caused by shrinkage due to heat.

The prepared each third sheet 53 is then attached via adhesive 30 to the one main surface 12A of the second insulating base material 12 which has been formed thereon with the second conductive circuit patterns 22 made already.

Thereafter, although not shown, the third sheet 53 is attached to the one main surface 12A side of the second insulating base material 12 by using pressing molds to press them from both main surface sides under a predetermined heating/pressurization environment. (b) of the same figure illustrates the third sheets 53, the second insulating base material 12, and the first insulating base material 11 integrated with one another after being removed from the pressing molds not shown.

Subsequently, an etching process is performed using copper (II) chloride or alkali etchant liquid etc. to remove a predetermined portion of each third conductive layer 23P thereby forming third conductive circuit patterns 23 on one main surface 13A of the third insulating base material 13, as shown in (c) of the same figure. As previously described, since the predetermined portion of the third conductive layer 23P is removed by the etching process, the one main surface 13A of the third insulating base material 13 not formed thereon with the third conductive circuit patterns 23 is roughened. Therefore, the adhesion properties are allowed to be enhanced between the one main surface 13A of the third insulating base material 13 within a region not formed thereon with the third conductive circuit patterns 23 and the protecting layer 40, which will be described later. Note that, if plural layers of third insulating base materials 13 are laminated, the adhesion properties among the third insulating base materials 13 may also be enhanced.

After forming the third conductive circuit patterns 23, if one or more additional layers of third insulating base materials 13 are laminated, steps of (b) and (c) of the same figure are repeated.

After achieving a target number of the laminated third insulating base materials 13, if any, the protecting layer 40 is laminated on the insulating base material placed as each uppermost layer (the third insulating base material 13 in the present example) to cover the third conductive circuit patterns 23, as shown in (d) of the same figure. The protecting layer 40 is not particularly limited in its fashion, and it may be formed by using a dispenser for applying epoxy-resin-base or polyimide-resin-base cover coat ink, or a sheet-like protection sheet may also be used.

Finally, as shown in (e) of the same figure, the pressing from both main surfaces is performed by using pressing molds under a predetermined heating/pressurization environment to integrate the protecting layers 40, the third sheets 53, the second insulating base material 12, and the first insulating base material 11 with one another, thereby providing the previously described partially multilayered wiring board 1 as shown in FIG. 1A and FIG. 1B.

As described hereinbefore, according to the manufacturing method of the first embodiment, the second conductive circuit patterns 22 are formed after laminating the second sheet 52 on the first conductive circuit patterns 21, and therefore, the first conductive circuit patterns 21 are allowed to be covered by the other main surface 12B of the second insulating base material 12 in spite of the existence of the conductive circuit patterns 20 on the first insulating base material 11 side (lower layer side). Consequently, a cover layer is not required to be separately provided on the conductive circuit patterns 20 other than portions on which multilayered portions 2 are provided, thereby simplifying the production steps.

More specifically, if multilayered boards each having an insulating layer and a conductive layer are separately formed and then laminated to produce a board, then conductive circuits are exposed at regions other than multilayered portions, and one or more cover layers must thus be formed on these regions other than multilayered portions. In contrast, according to the partially multilayered wiring board 1 of the present embodiment, a cover is not required to be separately provided because the first conductive circuit patterns 21 are covered by the other main surface of the second insulating base material 12 which has been formed thereon with the second conductive circuit patterns 22 to be each multilayered portion 2. As a result, the production steps are allowed to be simplified.

In addition, according to the manufacturing method of the present embodiment, no cover layer is required to be provided and no gap is thus created between each multilayered portion 2 and such a cover layer, and therefore, it is not necessary to perform gold plating or the like in order to fill such a gap. Also in this respect, the production steps are possible to be simplified. Consequently, according to the method of manufacturing the partially multilayered wiring board of the present embodiment, partially multilayered wiring boards can be provided which allow the material cost to be reduced and which are more flexible compared to the conventional method.

### Second Embodiment

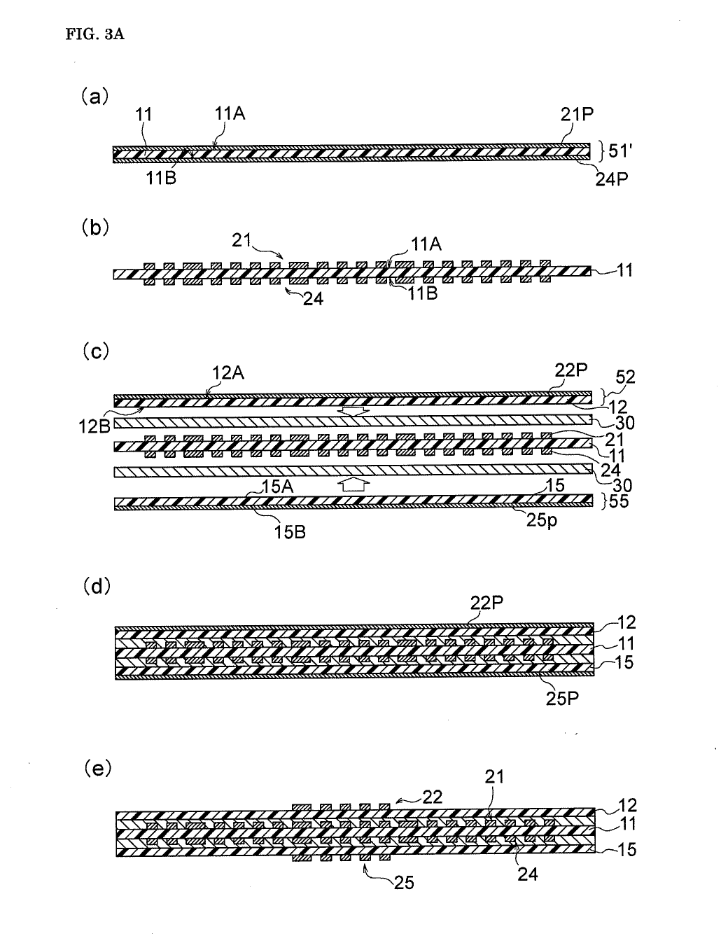

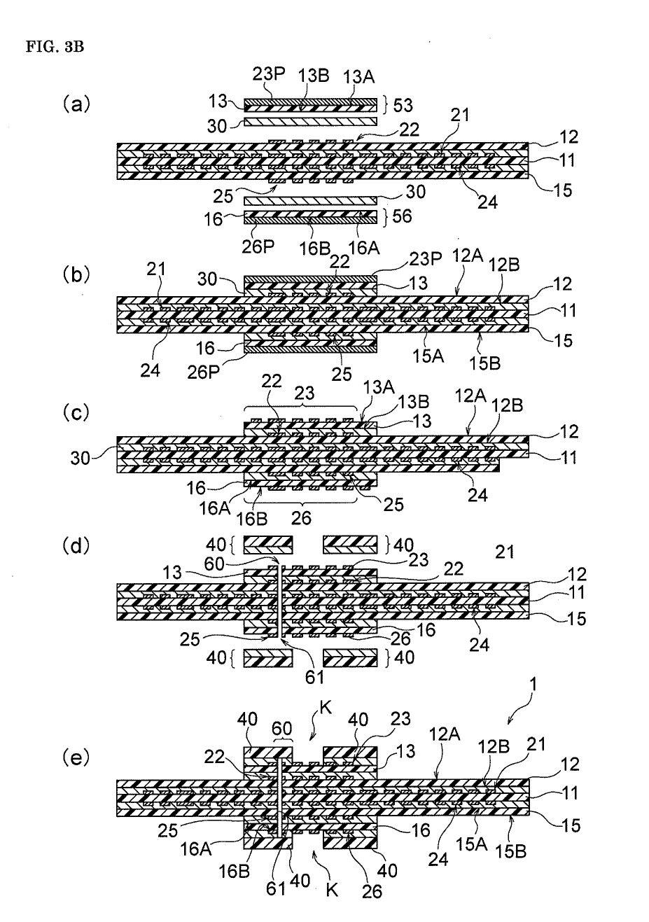

Hereinafter, another method of manufacturing partially multilayered wiring board 1 according to the second embodiment of the present invention will be described with reference to FIG. 3A and FIG. 3B. The partially multilayered wiring board 1 is one in which multilayered portions 2 are formed on both main surfaces of first insulating base material 11. FIG. 3A illustrates steps of forming second conductive circuit patterns 22 and fifth conductive circuit patterns 25, and FIG. 3B illustrates steps of forming third conductive circuit patterns 23 and sixth conductive circuit patterns 26, and protecting layers 40 covering them.

First, a first sheet 51′ is prepared. As shown in (a) of FIG. 3A, the first sheet 51′ is a sheet in which metal foils, such as copper, are formed on both main surfaces of a resin sheet (first insulating base material 11), such as polyimide (PI), having flexibility and being of thickness of 10 μm to 75 μm. Specifically, first conductive layer 21P is attached to one main surface 11A of the first insulating base material 11, while fourth conductive layer 24P is attached to the other main surface 11B.

Subsequently, one or more etching processes are performed using copper (II) chloride or alkali etchant liquid etc. to remove a predetermined portion of the first conductive layer 21P and also remove a predetermined portion of the fourth conductive layer 24P. Thus, as shown in (b) of the same figure, first conductive circuit patterns 21 are formed on the one main surface 11A of the first insulating base material 11, while fourth conductive circuit patterns 24 are formed on the other main surface 11B of the first insulating base material 11. Surfaces of regions within both the main surfaces 11A and 11B of the first insulating base material 11 not formed thereon with the first conductive circuit patterns 21 and the fourth conductive circuit patterns 24 due to etching processes are roughened.

In addition, prior to or subsequent to the above steps shown in (a), (b) of the same figure, a second sheet 52 is prepared in which a second conductive layer 22P is laminated on one main surface 12A of second insulating base material 12, and a fifth sheet 55 is also prepared in which a fifth conductive layer 25P is formed on other main surface 15B (opposing one main surface 15A) of fifth insulating base material 15. It is preferred in the present embodiment that the second sheet 52 and the fifth sheet 55 are sheets of the same quality as the first sheet 51.

Thereafter, as shown in (c) of the same figure, the prepared second sheet 52 and fifth sheet 55 are attached via adhesives 30 to both the main surfaces 11A and 11B, respectively, of the first insulating base material 11 which have been formed thereon with the first conductive circuit patterns 21 and the fourth conductive circuit patterns 24 made in the step shown in (b) of the same figure.

Further, although not shown, the second sheet 52 and the fifth sheet 55 are attached to both the main surfaces 11A and 11B of the first insulating base material 11 by using pressing molds to press them from both main surface sides under a predetermined heating/pressurization environment.

(d) of the same figure illustrates the second sheet 52, the fifth sheet 55, and the first insulating base material 11 integrated with one another after being removed from the pressing molds.

Furthermore, one or more etching processes are performed using copper (II) chloride or alkali etchant liquid etc. to remove a predetermined portion of the second conductive layer 22P and also remove a predetermined portion of the fifth conductive layer 25P.

Consequently, as shown in (e) of the same figure, second conductive circuit patterns 22 are formed on the one main surface 12A of the second insulating base material 12, while fifth conductive circuit patterns 25 are formed on the other main surface 15B of the fifth insulating base material 15.

As previously described, since the predetermined portions of the second conductive layer 22P and the fifth conductive layer 25P are removed by the etching processes, the one main surface 12A of the second insulating base material 12 and the other main surface 15B of the fifth insulating base material 15 not formed thereon with the second conductive circuit patterns 22 and the fifth conductive circuit patterns 25 are roughened. Therefore, the adhesion properties are allowed to be enhanced between the one main surface 12A of the second insulating base material 12 and other main surfaces 13B of third insulating base materials 13 which will be described later, and between the other main surface 15B of the fifth insulating base material 15 and one main surfaces 16A of sixth insulating base materials 16 which will also be described later.

With reference to FIG. 3B, the steps will then be described for forming the third conductive circuit patterns 23 and the sixth conductive circuit patterns 26, and the protecting layers 40 covering them.

First, as shown in (a) of FIG. 3B, each third sheet 53 is prepared in which a third conductive layer 23P is laminated on one main surface 13A of third insulating base material 13, while each sixth sheet 56 is prepared in which a sixth conductive layer 26P is laminated on other main surface 16B (opposing one main surface 16A) of sixth insulating base material 16. The third sheet 53 and the sixth sheet 56 are formed as being smaller than the first sheet 51. It is preferred in the present embodiment that the third sheet 53 and the sixth sheet 56 are sheets of the same quality as the first sheet 51.

Thereafter, the prepared each third sheet 53 is laminated via adhesive 30 on the one main surface 12A side of the second insulating base material 12 which has been formed thereon with the second conductive circuit patterns 22 made already. Similarly, the sixth sheet 56 is laminated via adhesive 30 on the other main surface 15B side of the fifth insulating base material 15 which has been formed thereon with the fifth conductive circuit patterns 25 made already.

The third sheet 53 is attached to the one main surface 12A side of the second insulating base material 12, while the sixth sheet 56 is attached to the other main surface 15B side of the fifth insulating base material 15, by using pressing molds to press them from both main surface sides under a predetermined heating/pressurization environment.

(b) of the same figure illustrates the third sheets 53, the second insulating base material 12, the first insulating base material 11, and the sixth sheets 56 integrated with one another after being removed from the pressing molds not shown.

Subsequently, one or more etching processes are performed to remove a predetermined portion of each third conductive layer 23P and also remove a predetermined portion of each sixth conductive layer 26P thereby forming third conductive circuit patterns 23 on one main surface 13A of the third insulating base material 13 while forming sixth conductive circuit patterns 26 on the other main surface 16B of the sixth insulating base material 16, as shown in (c) of the same figure. Similarly to the examples shown in FIG. 2A and FIG. 2B, the one main surface 13A of the third insulating base material 13 not formed thereon with the third conductive circuit patterns 23 and the other main surface 16B of the sixth insulating base material 16 not formed thereon with the sixth conductive circuit patterns 26 are roughened. Therefore, likewise the previously described examples, the adhesion properties are allowed to be enhanced between the laminated layers, such as the protecting layers 40 as will be described later.

After forming the third conductive circuit patterns 23 and the sixth conductive circuit patterns 26, if one or more additional layers of third insulating base materials 13 and/or sixth conductive circuit patterns 26 are laminated, steps of (a) to (c) of the same figure are repeated.

Thereafter, as shown in (d) of the same figure, one or more through-holes 60 are formed in the vertical direction through the partially multilayered wiring board 1 using drill or laser within a location where the second conductive circuit patterns 22, the third conductive circuit patterns 23, the fourth conductive circuit patterns 24, and the fifth conductive circuit patterns 25 are formed. Plating layers 61 are formed on inner surface of the through-holes 60 by performing copper plating using common non-electrolytic copper plating method or electrolytic copper plating method. Of course, the plating layers 61 may be formed of any conductive materials, such as other metals.

After achieving a target number of the laminated third insulating base materials 13 and the sixth insulating base materials 16, if any, protecting layers 40 are laminated on the insulating base materials placed as the uppermost layers (the third insulating base material 13 and the sixth insulating base material 16 in the present example) to cover the third conductive circuit patterns 23 and the sixth conductive circuit patterns 26, respectively, as shown in (d) of the same figure.

Finally, as shown in (e) of the same figure, the pressing from both main surfaces is performed by using pressing molds under a predetermined heating/pressurization environment to integrate the protecting layers 40, the third sheets 53, the second insulating base material 12, the first insulating base material 11, the fifth insulating base materials 15, and the sixth insulating base materials 16 with one another, thereby providing the partially multilayered wiring board 1.

As described hereinbefore, according to the manufacturing method of the second embodiment for the partially multilayered wiring board 1, the second conductive circuit patterns 22 and/or the fifth conductive circuit patterns 25 are formed after laminating the second sheet 52 and/or the fifth sheet 55 on the first conductive circuit patterns 21 and/or the fourth conductive circuit patterns 24, and therefore, the conductive circuit patterns 21 and 24 of the first insulating base material 11 are allowed to be covered by the other main surface 12B of the second insulating base material 12 and the one main surface 15A of the fifth insulating base material 15. Consequently, cover layers are not required to be separately provided on the conductive circuit patterns 20 other than portions on which multilayered portions 2 are provided, thereby simplifying the production steps.

More specifically, if multilayered boards each having an insulating layer and a conductive layer are separately formed and then laminated to produce a board, then conductive circuits are exposed at regions other than multilayered portions, and one or more cover layers must thus be formed on these regions other than multilayered portions. In contrast, according to the partially multilayered wiring board 1 of the present embodiment, covers are not required to be separately provided because the first conductive circuit patterns 21 are covered by the other main surface 12B of the second insulating base material 12 which has been formed thereon with the second conductive circuit patterns 22 to be each multilayered portion 2 while the fourth conductive circuit patterns 24 are covered by the one main surface 15A of the fifth insulating base material 15 which has been formed thereon with the fifth conductive circuit patterns 25. As a result, the production steps are allowed to be simplified.

In addition, according to the manufacturing method of the present embodiment, no cover layer is required to be provided and no gap is thus created between each multilayered portion 2 and such a cover layer, and therefore, it is not necessary to perform gold plating or the like in order to fill such a gap. Also in this respect, the production steps are possible to be simplified. Consequently, according to the method of manufacturing the partially multilayered wiring board of the present embodiment, partially multilayered wiring boards can be provided which allow the material cost to be reduced and which are more flexible compared to the conventional method.

It is to be noted that the embodiments as explained above are described to facilitate understanding of the present invention and are not described to limit the present invention. Therefore, it is intended that the elements disclosed in the above embodiments include all design changes and equivalents to fall within the technical scope of the present invention.

### Description of Reference Numerals

1 . . . partially multilayered wiring board
2 . . . multilayered portion
10 . . . insulating base material
11 . . . first insulating base material,
12 . . . second insulating base material,
13 . . . third insulating base material,
15 . . . fifth insulating base material,
16 . . . sixth insulating base material
20 . . . conductive circuit pattern
21 . . . first conductive circuit pattern,
22 . . . second conductive circuit pattern,
23 . . . third conductive circuit pattern,
24 . . . fourth conductive circuit pattern,
25 . . . fifth conductive circuit pattern,
26 . . . sixth conductive circuit patterns 26
30 . . . adhesive
40 . . . protecting layer
51 . . . first sheet,
52 . . . second sheet,
53 . . . third sheet
60 . . . through-hole
61 . . . plating layer

What is claimed is:

1. A partially multilayered wiring board comprising:
a first insulating base material having one main surface formed thereon with a first conductive circuit pattern; and
a second insulating base material laminated on a side of the one main surface of the first insulating base material and having one main surface formed thereon with a second conductive circuit pattern smaller than a region where the first conductive circuit pattern is formed,
wherein the first conductive circuit pattern is covered by other main surface of the second insulating base material.

2. The partially multilayered wiring board as set forth in claim 1, wherein a region not formed thereon with the first conductive circuit pattern within the one main surface of the first insulating base material and/or a region not formed thereon with the second conductive circuit pattern within the one main surface of the second insulating base material are/is roughened.

3. The partially multilayered wiring board as set forth in claim 1, further comprising a third insulating base material laminated on a side of the one main surface of the second insulating base material and having one main surface formed thereon with a third conductive circuit pattern,
wherein the third insulating base material is laminated on the second insulating base material such that the one main surface of the second insulating base material is contacted with other main surface of the third insulating base material.

4. The partially multilayered wiring board as set forth in claim 1, further comprising:
a fourth conductive pattern formed on other main surface of the first insulating base material;
a fifth insulating base material laminated on a side of the other main surface of the first insulating base material and having other main surface, of one and other main surfaces, formed thereon with a fifth conductive circuit pattern smaller than a region where the fourth conductive circuit pattern is formed; and
a sixth insulating base material laminated on a side of the other main surface of the fifth insulating base material and having other main surface, of one and other main surfaces, formed thereon with a sixth conductive circuit pattern,
wherein the fourth conductive circuit pattern is covered by the one main surface of the fifth insulating base material, and the fifth conductive circuit pattern is covered by the one main surface of the sixth insulating base material.

5. The partially multilayered wiring board as set forth in claim 3, having:
a fourth conductive pattern formed on other main surface of the first insulating base material;
a fifth insulating base material laminated on a side of the other main surface of the first insulating base material and having other main surface, of one and other main surfaces, formed thereon with a fifth conductive circuit pattern smaller than a region formed thereon with the fourth conductive circuit pattern; and
a sixth insulating base material laminated on a side of the other main surface of the fifth insulating base material and having other main surface, of one and other main surfaces, formed thereon with a sixth conductive circuit pattern,
wherein the fourth conductive circuit pattern is covered by the one main surface of the fifth insulating base material, and the fifth conductive circuit pattern is covered by the one main surface of the sixth insulating base material.

6. A method of manufacturing a partially multilayered wiring board, the method comprising:
preparing a first sheet in which a first conductive layer is laminated on one main surface of a first insulating base material and a second sheet in which a second conductive layer is laminated on one main surface of a second insulating base material;
removing a predetermined portion of the first conductive layer of the first sheet to form a first conductive circuit pattern on the one main surface of the first insulating base material;
attaching the second sheet such that the first conductive circuit pattern is covered by other main surface of the second insulating base material; and
removing a predetermined portion of the second conductive layer of the attached second sheet to form a second conductive circuit pattern on the one main surface of the second insulating base material.

7. The method of manufacturing a partially multilayered wiring board as set forth in claim 6, further comprising a step of preparing a third sheet in which a third conductive layer is laminated on one main surface of a third insulating base material,
wherein the third sheet is attached such that the second conductive circuit pattern is contacted with other main surface of the third insulating base material after the second conductive circuit pattern has been formed, and
a predetermined portion of the third conductive layer of the attached third sheet is removed to form a third conductive circuit pattern on the one main surface of the third insulating base material.

8. The method of manufacturing a partially multilayered wiring board as set forth in claim 6, wherein a protecting layer is formed to cover a conductive circuit pattern of an insulating base material placed as an uppermost layer.
